(19) United States
(12) Patent Application Publication
(10) Pub. No.: US 2009/0050929 A1
(43) Pub. Date: Feb. 26, 2009

(54) SEMICONDUCTOR SUBSTRATE WITH NITRIDE-BASED BUFFER LAYER FOR EPITAXY OF SEMICONDUCTOR OPTO-ELECTRONIC DEVICE AND FABRICATION THEREOF

(76) Inventors: Miin-Jang CHEN, Taipei City (TW); Wen-Ching Hsu, Hsinchu City (TW); Suz-Hua Ho, Jhudong Township (TW)

Correspondence Address: Muncy, Geissler, Olds & Lowe, PLLC, P.O. BOX 1364, FAIRFAX, VA, 22038-1364, US

(21) Appl. No.: 12/196,859

(22) Filed: Aug. 22, 2008

(30) Foreign Application Priority Data
Aug. 24, 2007 (TW) 096131338

(51) Int. Cl. H01L 33/00; H01L 21/00

(52) U.S. Cl. 257/103; 438/45; 257/E33.023

(57) ABSTRACT

The invention discloses a semiconductor substrate for epitaxy of a semiconductor optoelectronic device and the fabrication thereof. The semiconductor substrate according to the invention includes a substrate, and a nitride-based buffer layer. The buffer layer is formed by an atomic layer deposition process and/or a plasma-enhanced (or a plasma-assisted) atomic layer deposition process on an upper surface of the substrate. The nitride-based buffer layer assists the epitaxial growth of a semiconductor material layer of the semiconductor optoelectronic device.

### BACKGROUND OF THE INVENTION

1. Field of the Invention

The present invention relates to a semiconductor substrate and, more particularly, to a semiconductor substrate for epitaxy of a semiconductor opto-electronic device.

2. Description of the Prior Art

The current semiconductor opto-electronic devices, such as light-emitting diodes or photodetectors, have been used for a wide variety of applications, e.g. optical displaying devices, traffic lights, communication devices and illumination devices. To ensure high functional reliability as great as possible and a low power requirement of the semiconductor opto-electronic devices, the overall efficiency is required for the devices.

Inside the semiconductor light-emitting device of the prior art, a buffer layer can be formed between the substrate and the semiconductor material layer to enhance the epitaxial quality of the semiconductor material layer. So far, most of the substrates of the GaN-based semiconductor opto-electronic devices (e.g. light-emitting diodes or photodetectors) are made of sapphire. Because there is a poor crystalline lattice match between the GaN-based semiconductor material layer and the sapphire substrate, the epitaxial quality of the GaN-based semiconductor material layer is still required for improvement. As a result, an ideal buffer layer is necessary between the GaN-based semiconductor material layer and the sapphire substrate to improve the epitaxial quality of the GaN semiconductor material layer and further increase the efficiency of the semiconductor opto-electronic device.

Accordingly, the main scope of the invention is to provide a semiconductor substrate for epitaxy of a semiconductor opto-electronic device to solve the above problems.

### SUMMARY OF THE INVENTION

One scope of the invention is to provide a semiconductor substrate for epitaxy of a semiconductor opto-electronic device and a fabricating method thereof.

According to an embodiment of the invention, the semiconductor substrate includes a substrate and a buffer layer. The nitride-based buffer layer is formed by an atomic layer deposition process and/or a plasma-enhanced (or a plasma-assisted) atomic layer deposition process on an upper surface of the substrate. The nitride-based buffer layer can assist the epitaxial growth of a semiconductor material layer of the semiconductor opto-electronic device.

According to another embodiment of the invention, it is related to a method of fabricating a semiconductor substrate for epitaxy of a semiconductor opto-electronic device.

First, a substrate is prepared. Subsequently, a nitride-based buffer layer is formed on an upper surface of the substrate by an atomic layer deposition process and/or a plasma-enhanced (or a plasma-assisted) atomic layer deposition process. The nitride-based buffer layer can assist the epitaxial growth of a semiconductor material layer of the semiconductor opto-electronic device.

Compared to the prior art, during the epitaxial growth of the semiconductor material layer (e.g. a GaN layer) of the semiconductor opto-electronic device, the nitride-based buffer layer according to the invention can assist the epitaxial growth of the semiconductor material layer to improve the epitaxial quality of the semiconductor material layer and further enhance the efficiency of the semiconductor opto-electronic device.

The advantage and spirit of the invention may be understood by the following recitations together with the appended drawings.

### BRIEF DESCRIPTION OF THE APPENDED DRAWINGS

FIG. 1 illustrates a sectional view of a semiconductor substrate according to an embodiment of the invention.

FIG. 2A and FIG. 2B illustrate sectional views to describe a method of fabricating a semiconductor substrate according to another embodiment of the invention.

### DETAILED DESCRIPTION OF THE INVENTION

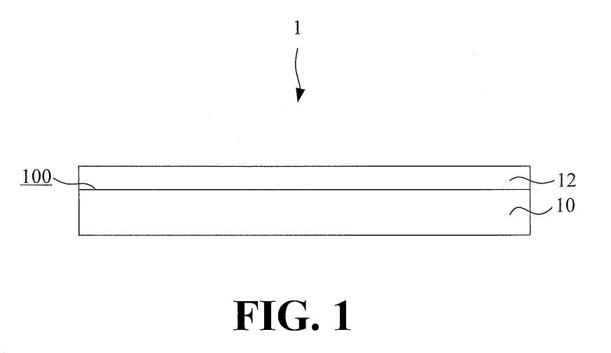

Please refer to FIG. 1. FIG. 1 illustrates a sectional view of a semiconductor substrate 1 according to an embodiment of the invention. In practical applications, the semiconductor substrate 1 can be used for epitaxy of a semiconductor opto-electronic device, such as a light-emitting diode or a light detector.

As shown in FIG. 1, the semiconductor substrate 1 includes a substrate 10 and a nitride-based buffer layer 12. In practical applications, the substrate 10 can be made of sapphire, Si, SiC, GaN, ZnO, ScAlMgO₄, YSZ (Yttria-Stabilized Zirconia), SrCu₂O₂, LiGaO₂, LiAlO₂, GaAs and the like.

In one embodiment, the nitride-based buffer layer 12 can be made of AlN. In addition, the buffer layer 12 can have a thickness in a range of 10 nm to 500 nm, but not limited therein. The nitride-based buffer layer 12 according to the invention is formed by an atomic layer deposition process and/or a plasma-enhanced (or a plasma-assisted) atomic layer deposition process on an upper surface 100 of the substrate 10. The nitride-based buffer layer 12 can assist the epitaxial growth of a semiconductor material layer of the semiconductor opto-electronic device. In one embodiment, the semiconductor material layer can be made of GaN, InGaN, or AlGaN.

In the embodiment, the substrate 10 is made of sapphire; the nitride-based buffer layer 12 is made of AlN; and the semiconductor material layer is made of GaN. Because there is a good crystalline lattice match between AlN and GaN, the buffer layer 12 of AlN can assist the epitaxial growth of the semiconductor material layer of GaN.

In practical applications, the precursors of AlN can be NH₃ and AlCl₃, Al(CH₃)₃, Al(CH₃)₂Cl, Al(C₂H₅)₃, ((CH₃)₃N)AlH₃, or ((CH₃)₂(C₂H₅)N)AlH₃. In one embodiment, the precursors of AlN can be AlCl₃ and NH₃; where the Al element is from AlCl₃, and the N element is from NH₃.

Taking the deposition of the buffer layer 12 of AlN as an example, an atomic layer deposition cycle includes four reaction steps of:

1. Using a carrier gas to carry NH₃ molecules into the reaction chamber, thereby the NH₃ molecules are absorbed on the upper surface 100 of the substrate 10 to form a layer of NH₂ radicals, where the exposure period is 0.1 second;

2. Using a carrier gas to purge the NH₃ molecules not absorbed on the upper surface 100 of the substrate 10, where the purge time is 5 seconds;

3. Using a carrier gas to carry Al(CH₃)₃ molecules into the reaction chamber, thereby the Al(CH₃)₃ molecules react with the NH₂ radicals absorbed on the upper surface 100 of the substrate 10 to form one monolayer of AlN, wherein a by-product is organic molecules, where the exposure period is 0.1 second; and

4. Using a carrier gas to purge the residual Al(CH₃)₃ molecules and the by-product due to the reaction, where the purge time is 5 seconds.

The carrier gas can be highly-pure argon or nitrogen. The above four steps, called one cycle of the atomic layer deposition, grows a thin film with single-atomic-layer thickness on the whole area of the substrate 10. The property is called self-limiting capable of controlling the film thickness with a precision of one atomic layer in the atomic layer deposition. Thus, controlling the number of cycles of atomic layer deposition can precisely control the thickness of the AlN buffer layer 12.

In conclusion, the atomic layer deposition process adopted by the invention has the following advantages: (1) able to control the formation of the material in nano-metric scale; (2) able to control the film thickness more precisely; (3) able to have large-area production; (4) having excellent uniformity; (5) having excellent conformality; (6) pinhole-free structure; (7) having low defect density; and (8) low deposition temperature, etc.

In practical applications, the deposition of the nitride-based buffer layer 12 can be performed at a processing temperature ranging from 300° C. to 1200° C. Further, the nitride-based buffer layer 12 can be annealed at a temperature ranging from 400° C. to 1200° C. for enhancing the quality of the nitride-based buffer layer 12.

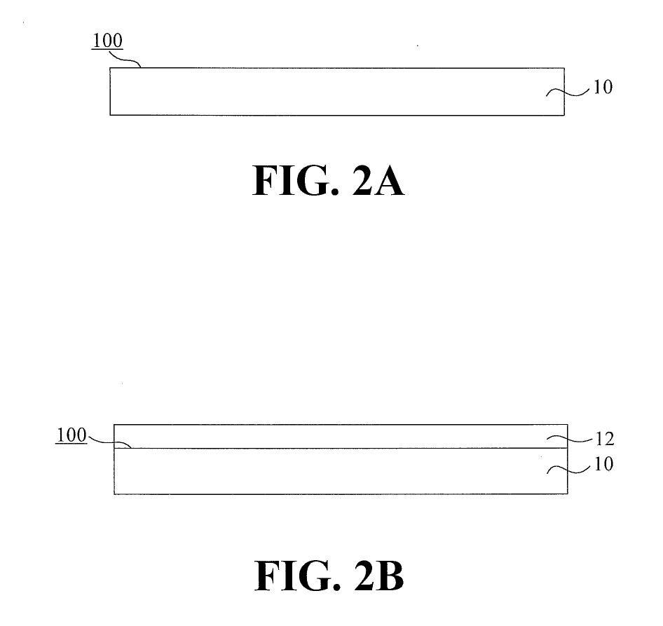

Please refer to FIG. 2A, FIG. 2B and together with FIG. 1. FIG. 2A and FIG. 2B illustrate sectional views to describe a method of fabricating a semiconductor substrate 1 according to another embodiment of the invention. The semiconductor substrate 1 can be used for epitaxy of a semiconductor opto-electronic device, such as a light-emitting diode or a photodetector.

First, a substrate 10 is prepared, as shown in FIG. 2A.

Subsequently, a nitride-based buffer layer 12 is formed on an upper surface 100 of the substrate 10 by an atomic layer deposition process and/or a plasma-enhanced (or a plasma-assisted) atomic layer deposition process. The nitride-based buffer layer 12 can assist a semiconductor material layer of the semiconductor opto-electronic device in epitaxy. In one embodiment, the nitride-based buffer layer 12 can be made of AlN, but not limited therein.

Compared to the prior art, during the epitaxial process of the semiconductor material layer (e.g. a GaN layer) of the semiconductor opto-electronic device, the nitride-based buffer layer according to the invention can assist the epitaxial growth of the semiconductor material layer to improve the epitaxial quality of the semiconductor material layer and further enhance the efficiency of the semiconductor opto-electronic device.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor substrate for epitaxy of a semiconductor opto-electronic device, comprising:
a substrate; and
a nitride-based buffer layer, formed by an atomic layer deposition process and/or a plasma-enhanced (or a plasma-assisted) atomic layer deposition process on an upper surface of the substrate, wherein the nitride-based buffer layer assists the epitaxial growth of a semiconductor material layer of the semiconductor opto-electronic device.

2. The semiconductor substrate of claim 1, wherein the nitride-based buffer layer is made of AlN.

3. The semiconductor substrate of claim 2, wherein the nitride-based buffer layer has a thickness in a range of 10 nm to 500 nm.

4. The semiconductor substrate of claim 2, wherein the semiconductor material layer is made of a material selected from the group consisting of GaN, InGaN, and AlGaN.

5. The semiconductor substrate of claim 2, wherein the precursors of the nitride-based buffer layer are NH₃ and AlCl₃, Al(CH₃)₃, Al(CH₃)₂Cl, Al(C₂H₅)₃, ((CH₃)₃N)AlH₃, or ((CH₃)₂(C₂H₅)N)AlH₃.

6. The semiconductor substrate of claim 2, wherein the deposition of the nitride-based buffer layer is performed at a processing temperature ranging from 300° C. to 1200° C.

7. The semiconductor substrate of claim 6, wherein the nitride-based buffer layer is further annealed at a temperature ranging from 400° C. to 1200° C.

8. The semiconductor substrate of claim 4, wherein the substrate is made of a material selected from the group consisting of sapphire, Si, SiC, GaN, ZnO, ScAlMgO₄, YSZ (Yttria-Stabilized Zirconia), SrCu₂O₂, LiGaO₂, LiAlO₂, and GaAs.

9. The semiconductor substrate of claim 8, wherein the substrate is made of sapphire, the nitride-based buffer layer is made of AlN, and the semiconductor material layer is made of GaN.

10. A method of fabricating a semiconductor substrate for epitaxy of a semiconductor opto-electronic device, said method comprising the steps of:
preparing a substrate; and
by an atomic layer deposition process and/or a plasma-enhanced (or a plasma-assisted) atomic layer deposition process, forming a nitride-based buffer layer on an upper surface of the substrate, wherein the nitride-based buffer layer assists the epitaxial growth of a semiconductor material layer of the semiconductor opto-electronic device.

11. The method of claim 10, wherein the nitride-based buffer layer is made of AlN.

12. The method of claim 11, wherein the nitride-based buffer layer has a thickness in a range of 10 nm to 500 nm.

13. The method of claim 11, wherein the semiconductor material layer is made of a material selected from the group consisting of GaN, InGaN, and AlGaN.

14. The method of claim 11, wherein the precursors of the nitride-based buffer layer are NH₃ and AlCl₃, Al(CH₃)₃, Al(CH₃)₂Cl, Al(C₂H₅)₃, ((CH₃)₃N)AlH₃, or ((CH₃)₂(C₂H₅)N)AlH₃.

15. The method of claim 11, wherein the deposition of the nitride-based buffer layer is performed at a processing temperature ranging from 300° C. to 1200° C.

16. The method of claim 15, wherein the nitride-based buffer layer is further annealed at a temperature ranging from 400° C. to 1200° C.

17. The method of claim 13, wherein the substrate is made of a material selected from the group consisting of sapphire, Si, SiC, GaN, ZnO, ScAlMgCU, YSZ (Yttria-Stabilized Zirconia), SrCu₂O₂, LiGaO₂, LiAlO₂, and GaAs.

18. The method of claim 17, wherein the substrate is made of sapphire, the nitride-based buffer layer is made of AlN, and the semiconductor material layer is made of GaN.
